(19) United States
(12) Patent Application Publication
(10) Pub. No.: US 2020/0002568 A1
(43) Pub. Date: Jan. 2, 2020

(54) LITHOGRAPHIC COMPOSITIONS AND METHODS OF USE THEREOF

(71) Applicant: Merck Patent GmbH, Darmstadt (DE)

(72) Inventors: Huirong YAO, Plainsboro, NJ (US); Elizabeth WOLFER, Bethlehem, PA (US); JoonYeon CHO, Bridgewater, NJ (US); Orest POLISHCHUCK, Bayonne, NJ (US); M. Dalil RAHMAN, Flemington, NJ (US); Douglas S. Mackenzie, Easton, PA (US)

(21) Appl. No.: 16/484,362

(22) PCT Filed: Mar. 14, 2018
(86) PCT No.: PCT/EP2018/056322

§ 371 Date: Aug. 7, 2019

Related U.S. Application Data
(60) Provisional application No. 62/472,208, filed on Mar. 16, 2017.

(51) Int. Cl. C09D 181/06; C08G 75/23; C09D 171/00; C08G 65/40; H01L 21/02; H01L 21/033

(52) U.S. Cl. CPC C09D 181/06; C08G 75/23; C09D 171/00; H01L 21/02087; H01L 21/02186; H01L 21/0332; C08G 65/4012

(57) ABSTRACT

Masking compositions for preventing metal contamination at substrate edges during the manufacture of electronic devices. The masking compositions have a unit of structure (I): Also provided are methods of using the masking compositions for manufacturing electronic devices.

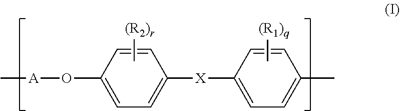

### FIELD OF THE INVENTION

The present invention relates to compositions and methods useful for the manufacture or treatment of substrates or semiconductor devices and, in particular, to compositions and methods useful for forming layers or masks on lithographic substrates or semiconductor devices.

### BACKGROUND OF THE INVENTION

Multiple antireflective layers and hardmasks are used in advanced lithographic patterning processes. For example, in cases where a photoresist does not provide sufficient dry etch resistance, underlayers and/or antireflective coatings for the photoresist that act as a hardmask and are highly etch resistant during substrate etching are preferred. One approach has been to incorporate silicon, titanium, zirconium, aluminum, or other metallic materials into a layer beneath the organic photoresist layer. Additionally, another high carbon content antireflective or mask layer may be placed beneath the metal containing antireflective layer, to create a trilayer of high carbon film/hard mask film/photoresist. Such layers can be used to improve the lithographic performance of the imaging process. However, metal contamination in the lithographic and etch tools, as well as cross contamination between wafers during manufacturing, should be avoided.

One process and apparatus for reducing metal contamination during the manufacture of integrated circuit components has been described in U.S. Pat. No. 8,791,030 (Iwao et al), which is hereby incorporated herein in its entirety. According to Iwao et al., a masking composition is supplied to an edge of the substrate and baked to form a masking film at the edge of the substrate. A hardmask composition is then coated on the substrate and the masking film. The portion of the hardmask composition overlying the masking film is removed using an edge bead remover and the hardmask composition is baked to form a hardmask. The masking film is then removed with a masking film removing solution. The result is a hardmask that is spaced from the edge of the substrate, thereby reducing contamination.

Accordingly, there is a need for masking compositions that can be supplied to an edge of a substrate and treated to form a masking film. In particular, it would be advantageous to provide masking compositions with properties that enable the solutions to be cast onto an edge of a substrate using, for example, spin on techniques. In addition, the masking compositions should produce masking films that do not significantly dissolve in the solvent used in the hardmask composition. Further, the masking films should not significantly dissolve in the edge bead remover. Even further, the masking films should be able to be removed without deleteriously affecting the hardmask. In particular, it would be useful for the masking films to be able to be removed by wet etching using a solvent that does not deleteriously affect the hardmask. In addition, it would be useful for the masking films to be able to be removed at a rate that enables commercially acceptable process times. The present disclosure addresses these needs.

### SUMMARY OF THE INVENTION

In one of its aspects, the present invention relates to masking compositions comprising:
a. a polymer comprising a unit having structure (I):

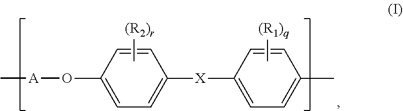

wherein
X is selected from the group consisting of —SO₂—, —C(═O)— and —O—;
A is a direct bond or A has structure (II):

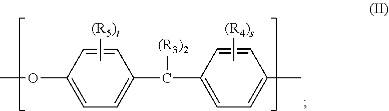

R₁, R₂, R₃, R₄ and R₅ are each independently selected from the group consisting of H, halo, (C₁₋₃) alkyl, (C₁₋₃) fluorinated alkyl, hydroxy, (C₁₋₃) alkoxy, (C₁₋₃) alkyl carbonyl; and
q, r, s and t are each independently selected from the group consisting of 0, 1, 2, 3 and 4; and
b. an organic solvent,
wherein the polymer has an average molecular weight of less than 50000.

In another of its aspects, the present invention relates to methods of manufacturing an electronic device comprising:
a. applying a masking composition onto an edge of a substrate, wherein the masking composition comprises:
   a polymer comprising a unit having structure (I):

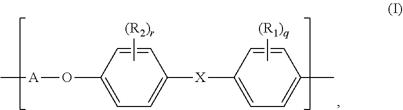

wherein
X is selected from the group consisting of —SO₂—, —C(═O)— and —O—;
A is a direct bond or A has structure (II):

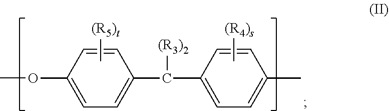

R₁, R₂, R₃, R₄ and R₅ are each independently selected from the group consisting of H, halo, (C₁₋₃) alkyl, (C₁₋₃) fluorinated alkyl, hydroxy, (C₁₋₃) alkoxy, (C₁₋₃) alkyl carbonyl; and
q, r, s and t are each independently selected from the group consisting of 0, 1, 2, 3 and 4; and
an organic solvent; and
b. heating the masking composition at a temperature between 150° C. and 350° C. and for a time between 60 s and 120 s to form a masking film.

In yet another of its aspects, the present invention relates to methods of manufacturing an electronic device comprising:
a. applying a masking composition onto an edge of a substrate, wherein the masking composition comprises:
   a polymer comprising a unit having structure (I):

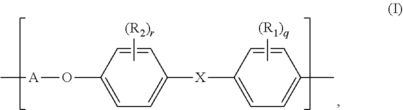

wherein
X is selected from the group consisting of —SO₂—, —C(═O)— and —O—;
A is a direct bond or A has structure (II):

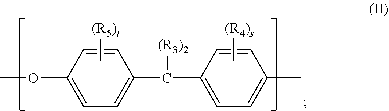

R₁, R₂, R₃, R₄ and R₅ are each independently selected from the group consisting of H, halo, (C₁₋₃) alkyl, (C₁₋₃) fluorinated alkyl, hydroxy, (C₁₋₃) alkoxy, (C₁₋₃) alkyl carbonyl; and
q, r, s and t are each independently selected from the group consisting of 0, 1, 2, 3 and 4; and
an organic solvent;
b. heating the masking composition to form a masking film;
c. applying a hardmask composition onto the substrate and the masking film;
d. rinsing the hardmask composition with an edge bead remover to remove at least a
portion of the hardmask composition that is in contact with the masking film;
e. heating the hardmask composition to form a hardmask; and
f. removing the masking film.

### BRIEF DESCRIPTION OF THE DRAWINGS

FIG. 1a-f shows a schematic representation of one embodiment of a process for using the masking compositions of the present invention. In FIG. 1a, a masking composition is applied onto an edge of a substrate. In FIG. 1b, the masking composition is heated to form a masking film. In FIG. 1c, a hardmask composition is applied onto the substrate and the masking film. In FIG. 1d, the hardmask composition is rinsed with an edge bead remover to remove at least a portion of the hardmask composition that is in contact with the masking film. In FIG. 1e, the hardmask composition is heated to form a hardmask. In FIG. 1f, the masking film is removed.

### DEFINITIONS

Unless otherwise stated, the following terms used in the specification and claims shall have the following meanings for the purpose of this Application.

In this application, the use of the singular includes the plural, and the words “a”, “an” and “the” mean “at least one”, unless specifically stated otherwise. Furthermore, the use of the term “including”, as well as other forms such as “includes” and “included”, is not limiting. Also, terms such as “element” or “component” encompass both elements or components comprising one unit and elements or components that comprise more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measureable numerical variable, refers to the indicated value of the variable and to all values of the variable that are within the experimental error of the indicated value (e.g., within the 95% confidence limit for the mean) or within ±10 percent of the indicated value, whichever is greater.

As used herein, “C_{x-y}” designates the number of carbon atoms in a chain. For example, C₁₋₆ alkyl refers to an alkyl chain having a chain of between 1 and 6 carbons (e.g., methyl, ethyl, propyl, butyl, pentyl and hexyl). Unless specifically stated otherwise, the chain can be linear or branched.

Unless otherwise indicated, alkyl refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). These alkyl moieties may be substituted or unsubstituted.

Fluorinated alkyl (a.k.a. Fluoroalkyl) refers to a linear, cyclic or branched saturated alkyl group as defined above in which one or more of the hydrogens have been replaced by fluorine (e.g., trifluoromethyl, perfluoroethyl, 2,2,2-trifluoroethyl, perfluoroisopropyl, perfluorocyclohexyl and the like). These fluoroalkyl moieties, if not perfluorinated, may be unsubstituted or further substituted.

Alkoxy (a.k.a. Alkyloxy) refers to an alkyl group as defined above which is attached through an oxy (—O—) moiety (e.g., methoxy, ethoxy, propoxy, butoxy, 1,2-isopropoxy, cyclopentyloxy, cyclohexyloxy and the like). These alkoxy moieties may be substituted or unsubstituted.

Alkyl carbonyl refers to an alkyl group as defined above which is attached through a carbonyl group (—C(═O—)) moiety (e.g., methylcarbonyl, ethylcarbonyl, propylcarbonyl, buttylcarbonyl, cyclopentylcarbonyl and the like). These alkyl carbonyl moieties may be substituted or unsubstituted.

Halo or halide refers to a halogen (e.g., F, Cl, Br, and I).

Hydroxy (a.k.a. Hydroxyl) refers to an —OH group.

Unless otherwise indicated, the term “substituted” when referring to an alkyl, alkoxy, fluorinated alkyl, and the like refers to one of these moieties which also contain one or more substituents, selected from the group consisting of unsubstituted alkyl, substituted alkyl, unsubstituted aryl, substituted aryl, alkyloxy, alkylaryl, haloalkyl, halide, hydroxy, amino and amino alkyl. Similarly, the term “unsubstituted” refers to these same moieties wherein no substituents apart from hydrogen are present.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed.

The masking compositions of the present invention are formed by a polymer and an organic solvent, wherein the polymer has a unit having structure (I):

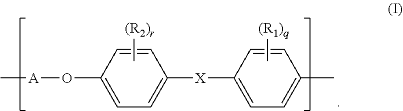

In one embodiment, X is —SO₂—. In a further embodiment, X is —C(═O)—. In another embodiment, X is —O—.

In structure (I), each R₁ is independently H, halo, (C₁₋₃) alkyl, (C₁₋₃) fluorinated alkyl, hydroxy, (C₁₋₃) alkoxy, or (C₁₋₃) alkyl carbonyl. In particular variations, each R₁ is independently H, F, or (C₁₋₃) alkyl.

In one variation, q is 0. In a further variation, q is 1. In another variation, q is 2. In still another variation, q is 3. In yet another variation, q is 4.

In structure (I), each R₂ is independently H, halo, (C₁₋₃) alkyl, (C₁₋₃) fluorinated alkyl, hydroxy, (C₁₋₃) alkoxy, or (C₁₋₃) alkyl carbonyl. In particular variations, each R₂ is independently H, F, or (C₁₋₃) alkyl.

In one variation, r is 0. In a further variation, r is 1. In another variation, r is 2. In still another variation, r is 3. In yet another variation, r is 4.

In structure (I), A can be a direct bond. Alternatively, A can have structure (II):

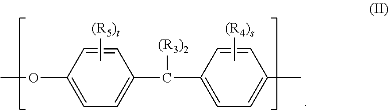

In structure (II), each R₃ is independently H, halo, (C₁₋₃) alkyl, (C₁₋₃) fluorinated alkyl, hydroxy, (C₁₋₃) alkoxy, or (C₁₋₃) alkyl carbonyl. In particular variations, each R₃ is independently H, F, (C₁₋₃) alkyl, or (C₁₋₃) fluorinated alkyl.

In structure (II), each R₄ is independently H, halo, (C₁₋₃) alkyl, (C₁₋₃) fluorinated alkyl, hydroxy, (C₁₋₃) alkoxy, or (C₁₋₃) alkyl carbonyl. In particular variations, each R₄ is independently H, F, or (C₁₋₃) alkyl.

In one variation, s is 0. In a further variation, s is 1. In another variation, s is 2. In still another variation, s is 3. In yet another variation, s is 4.

In structure (II), each R₅ is independently H, halo, (C₁₋₃) alkyl, (C₁₋₃) fluorinated alkyl, hydroxy, (C₁₋₃) alkoxy, or (C₁₋₃) alkyl carbonyl. In particular variations, each R₅ is independently H, F, or (C₁₋₃) alkyl.

In one variation, t is 0. In a further variation, t is 1. In another variation, t is 2. In still another variation, t is 3. In yet another variation, t is 4.

In one particular embodiment, the polymer has structure (III):

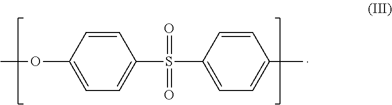

In another particular embodiment, the polymer has structure (IV):

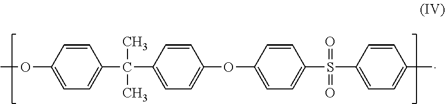

In another particular embodiment, the polymer has structure (V):

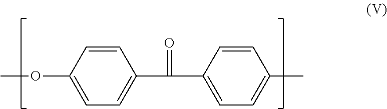

In another embodiment, the polymer has structure (VI):

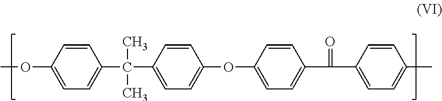

The molecular weight of the polymer can be selected to provide the desired etch rate. Toward that end, incorporation of polymers having low molecular weights will increase the etch rate. In this manner, the typically long etch times needed to process masking films which contain only polymers having high molecular weights can be beneficially reduced. Accordingly, in one embodiment, the polymer has an average molecular weight of not more than 50000. In another embodiment, the polymer has an average molecular weight of not more than 40000. In a further embodiment, the polymer has an average molecular weight of not more than 35000. In another embodiment, the polymer has an average molecular weight of not more than 30000.

However, the use of polymers with very low molecular weights can produce films that are too easily removed to be useful as masking films. Accordingly, in one embodiment, the polymer has an average molecular weight of at least 10000. In another embodiment, the polymer has an average molecular weight of at least 20000. In a further embodiment, the polymer has an average molecular weight of at least 28000.

The composition can comprise a single polymer. Alternatively, the composition can comprise a mixture of polymers. When the composition comprises a mixture of polymers, the mixture of polymers can comprise a first polymer having an average molecular weight greater than 40000 and a second polymer having an average molecular weight less than 40000. Alternatively, the mixture of polymers can comprise a first polymer having an average molecular weight greater than 30000 and a second polymer having an average molecular weight less than 30000. Further, the mixture of polymers can comprise a first polymer having an average molecular weight greater than 20000 and a second polymer having an average molecular weight less than 20000. The first polymer can be obtained from Aldrich and the second polymer can be synthesized.

In addition, when the composition comprises a mixture of a first polymer and a second polymer, one or both of the polymers can have a unit having structure (I). Accordingly, in one variation, the first polymer has a unit having structure (I). In a further variation, the second polymer has a unit having structure (I). In another variation, both the first polymer and the second polymer have a unit having structure (I).

Any of a variety of organic solvents can be used in the composition. In particular, the organic solvent can be anisole, cyclohexanone, gamma butyro lactone (GBL), N-methyl-2-pyrrolidone, di-(C₁₋₆) alkyl ketones, (C₁₋₆) alkyl acetates or mixtures thereof. Specific di-(C₁₋₆) alkyl ketones include, but are not limited to, butanone, cyclopentanone, ethyl isopropyl ketone, 2-hexanone, methyl isobutyl ketone, methyl isopropyl ketone, 3-methyl-2-pentanone, 2-pentanone, 3-pentanone and mixtures thereof. Specific (C₁₋₆) alkyl acetates include, but are not limited to, methyl acetate, ethyl acetate, n-propyl acetate, isopropyl acetate, n-butyl acetate, isobutyl acetate and mixtures thereof.

It will be understood by those skilled in the art that the solid content in the composition can be adjusted based on the desired film thickness. In certain variations, the polymer is present in the composition in an amount of at least 0.1 wt %. In other variations, the polymer is present in an amount of at least 3 wt %. In certain variations, the polymer is present in an amount of not more than 20 wt %. In other variations, the polymer is present in an amount of not more than 15 wt %.

Those skilled in the art will understand that the masking compositions of the present invention can be used to form a masking film in a variety of lithographic applications. In particular, the masking compositions of the present invention can be used to form an edge protecting layer. Toward that end, the masking composition can be applied onto an edge of a substrate and then treated to form the masking film. For example, the masking compositions can be cured at a temperature between 150° C. and 350° C. and for a time between 60 s and 120 s. The masking composition can be applied to the substrate using any of a variety of techniques known in the art. In particular, the masking composition can be applied onto the substrate by a spin-on coating process.

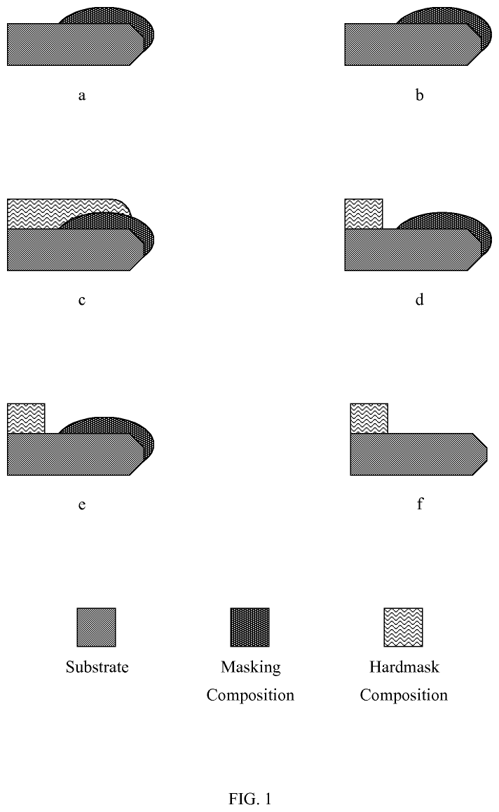

More specifically, referring to FIGS. 1a-f, the masking compositions of the present invention can be used in a method of manufacturing an electronic device. A masking composition is applied onto an edge of a substrate (FIG. 1a) and treated (e.g., by the application of heat) to form a masking film (FIG. 1b). The masking composition can optionally be treated to reduce impurities prior to application. For example, the masking composition can be treated to reduce trace metal by ion exchange. A hardmask composition is then applied onto the substrate and the masking film (FIG. 1c). The masking film and hardmask composition are rinsed with an edge bead remover to remove at least a portion of the hardmask composition that is in contact with the masking film (FIG. 1d). A portion or portions of the hardmask composition that are in contact with the masking film may remain even after rinsing, provided that the portions that remain do not significantly reduce the effectiveness of the masking layer. For example, up to about 5% of the hardmask composition that is inn contact with the masking film may remain after rinsing. The hardmask composition is then treated (e.g., by the application of heat) to form a hardmask (FIG. 1e). The masking film can then be removed, leaving the hardmask spaced from the edge of the substrate (FIG. 1f).

The masking composition can be applied onto the substrate using any of a variety of techniques that enables the masking composition to be applied onto an edge of the substrate. One technique for applying the masking composition using a spin-on coating process is described in U.S. Pat. No. 8,791,030 (Iwao et al.), which is hereby incorporated herein in its entirety. In certain embodiments, the masking composition is applied in a thickness of at least about 10 nm, at least about 50 nm, at least about 100 nm, at least about 200 nm, or at least about 300 nm. In addition, the masking composition is applied in a thickness of up to about 1000 nm, up to about 900 nm, or up to about 800 nm. Further, the masking composition is applied at a width of at least about 0.5 mm, or at least about 0.75 mm. Also, the masking composition is applied at a width of not more than about 1.5 mm, or not more than about 1.0 mm. Further, the masking composition is positioned to cover the edge of the substrate and to extend over the side and/or backside of the substrate.

Those skilled in the art would readily understand that the masking composition can be treated to form the masking film using any of a variety of techniques. For example, the masking film can be heated at a temperature between 150° C. and 350° C. and for a time between 60 s and 120 s.

Any of a variety of known hardmask compositions can be used. In one embodiment, the hardmask composition is a metal hardmask composition. Alternatively, the hardmask composition can be a metal oxide photoresist composition. Suitable metal hardmask and metal oxide photoresist compositions include, but are not limited to, those described in U.S. Pat. Nos. 9,315,636; 8,568,958, 9,201,305; 9,296,922; 9,409,793; and 9,499,698 and U.S. patent application Ser. Nos. 62/437,449 (filed Dec. 21, 2016) and 14/978,232 (filed Dec. 22, 2015), which are hereby incorporated herein in their entireties.

Any of a variety of techniques can be used to apply the hardmask composition onto the substrate. Suitable techniques include, but are not limited to, spin-on coating, chemical vapor deposition (CVD) and atomic layer deposition (ALD). When spin coating is utilized, the solvent used should not deleteriously affect the masking film. Accordingly, suitable casting solvents for the hardmask composition include, but is not limited to, PGMEA, PGME, ethyl lactate, methoxyethanol, ethoxypropanol, ethoxyethanol, 1-pentanol, 4-methyl-2-pentanol and mixtures thereof.

Any of a variety of techniques can be used to remove a portion of the hardmask composition that is in contact with the masking film. It would be understood by those skilled in the art that removal of a portion of the hardmask composition that is in contact with the masking film should not deleteriously affect that part of the hardmask composition that is not in contact with the masking film. Suitable techniques include, but are not limited to chemical mechanical polishing (CMP), plasma etching, and wet etching. When wet etching is utilized, any of a variety of solvents (such as edge bead removers) can be used provided that the solvent does not deleteriously affect the masking film or hardmask composition. Suitable edge bead removers include, but are not limited to, PGMEA, PGME, ethyl lactate, methoxyethanol, ethoxypropanol, ethoxyethanol, 1-pentanol, 4-methyl-2-pentanol and mixtures thereof.

The hardmask composition can be treated by a variety of techniques to form the hardmask. For example, the hardmask composition can be treated by heating at a temperature between 150° C. and 450° C. and for a time between 60 s and 120 s.

Any of a variety of techniques can be used to remove the masking film. Suitable techniques include, but are not limited to plasma etching, and wet etching. When wet etching is utilized, any of a variety of solvents can be used provided that the solvent does not deleteriously affect the hardmask. Suitable solvents include, but are not limited to, anisole, cyclohexanone, gamma butyro lactone (GBL), N-methyl-2-pyrrolidone, di-(C₁₋₆) alkyl ketones, (C₁₋₆) alkyl acetates, aromatic hydrocarbons and mixtures thereof.

Typical electronic devices that can be manufactured using the compositions and methods of the present invention include, but are not limited to computer chips, integrated circuits, and semiconductor devices.

### EXAMPLES

Reference will now be made to more specific embodiments of the present disclosure and experimental results that provide support for such embodiments. However, Applicants note that the disclosure below is for illustrative purposes only and is not intended to limit the scope of the claimed subject matter in any way.

### Synthesis Example 1

Bisphenol A (45.60 g, 0.20 mol), bis(p-chlorophenyl) sulfone (57.4 g, 0.20 mol), dried potassium carbonate (55.3 g, 0.40mol), 400 ml of DMA (dimethyl acetamide), and 50 ml of toluene were placed in a 2 L, 4 necked round bottom flask, fitted with a condenser, a nitrogen sweep, a Dean Stark trap (filled with toluene) and an overhead mechanical stirrer. The mixture was mixed at room temperature for 10 minutes.

The reaction mixture was heated at 150° C. for 9.5 hours on a heating mantle. The reaction mixture was then cooled to less than 50° C. and filtered through filter paper. The filtered solution (pH 9 to 10) was neutralized with 10% HCl to pH 7-6, and then poured into DI water (3200 mL) in a 5 L flask. A precipitate was formed. The mixture was mixed for 30 minutes and allowed to settle overnight. Water was decanted (3400 mL) and one liter THF was added to the sticky solid. After mixing, it was transferred to a beaker and heated on a hot plate to reduce volume to one liter. The polymer was precipitated by drowning the solution into 12 liter of hexane, mixing for 1 hour, and then letting the solids settle.

The solution was filtered through filter paper and washed with hexane. Polymer was dried in a vacuum oven for two days at 80° C. Obtained 85 g, GPC Mw 9769; Pd=2.23.

The FT IR spectrum shows peaks at 1245 cm⁻¹ characteristic of the C—O—C stretch of the aryl ether group, and at 1280-1320 cm⁻¹ corresponding to the O═S═O group.

The proton NMR spectrum shows peaks at 1.7 ppm due to the aliphatic group of isopropylidene group of bisphenol-A, and at 6-7.8 ppm corresponding to the aromatic protons.

### Synthesis Example 2

Bisphenol A (22.8 g, 0.10 mole), 4,4′-Difluorobenzophenone (21.8 g, 0.10 mole), potassium carbonate (27.6 g, 0.20 mole), 157 mL dimethylaceamide, and 21.4 mL toluene was placed into a 500 mL, 4 neck, round bottom flask equipped with stiffing, a condenser, a thermowatch, a dean stark trap filled with toluene, and nitrogen purge. The solution was mixed at room temp for 10 minutes, and then the temp was set to 150° C. Since reflux begins at 147° C., the solution was held at reflux for 90 minutes. The solution was then cooled to <70° C. The reaction solution was filtered to remove salts, and the filtrate was then neutralized using a small amount of 10% HCl. The polymer was precipitated by drowning the solution into 1600 mL of DI water, mixing for 1 hour, and then letting the solids settle.

The water layer was poured off, and then 500 mL of tetrahydrofuran was added. The solution was mixed for 30 minutes, transfered to a beaker and the volume was reduced to 600 mL on a hot plate. The polymer was precipitated by drowning into 3 liters of hexane, filtering, washing, drying, and leaving the polymer in a vacuum oven overnight. Obtain 27 g, GPC Mw 54,982, Pd=1.78.

### Synthesis Example 3

Bisphenol A (22.8 g, 0.10 mole), 4,4′-Difluorobenzophenone (21.8 g, 0.10 mole), potassium carbonate (27.6 g, 0.20 mole), 200 mL dimethylacetamide, and 27.5 mL toluene was placed into a 500 mL, 4 neck, round bottom flask equipped with stiffing, condenser, thermowatch, dean stark trap filled with toluene, and nitrogen purge. The solution was mixed at room temp for 10 minutes, and then the temperature was set to 150° C. Since reflux begins at 147° C., the solution was held at reflux for 90 minutes. The solution was then cooled to <70° C., filtered to remove salts, and the filtrate was then neutralize using a small amount of 10% HCl. The polymer was precipitated by drowning into 1600 mL of DI water, mixing for 1 hour, and then letting the solids settle.

The water layer was poured off, and then 500 mL of tetrahydrofuran was added. The solution was mixed for 30 minutes, transferred to a beaker and the volume was reduced to 600 mL on a hot plate. The polymer was precipitated by drowning into 3 liters of hexane, filtering, washing, drying, and leaving the polymer in a vacuum oven overnight. Obtain 37 g, GPC Mw 15,125 Pd=2.10.

### Process Examples 1 and 2

Examples of masking compositions of the present invention were made and tested. Process Example 1 was prepared by dissolving 1% of the polysulfone (PSU) in anisole. Process Example 2 was prepared by dissolving 1% of the polyethersulfone (PES) in gamma butyro lactone (GBL). The masking compositions were spin coated on the edge of a wafer and baked at either 250 or 350° C. for 60 s to form uniform films, in accordance with the technique described in U.S. Pat. No. 8,791,030 (Iwao et al).

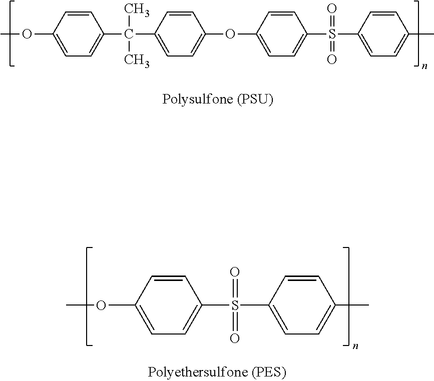

The solubilities of masking films formed from Process Examples 1 and 2 (after a 250° C./60 s bake) in various solvents were investigated by measuring film loss after immersing the coated wafer in solvent for 60 s. The results in Table 1 show that the masking films have good resistance to an ArF thinner solvent (PGMEA:PGME 70:30). Accordingly, there should be no intermixing between the masking films and a hardmask during processing. Further, the masking film formed from Example 1 can be removed by anisol and the masking film formed from Example 2 can be removed by GBL.

TABLE 1

| | | FT Before | FT After | Film | % |
|---|---|---|---|---|---|
| | Soak | Soak | Soak | Loss | Film |
| Formulation | Solvent | (Å) | (Å) | (Å) | Loss |
| 1% Polysulfone | ArF Thinner | 233 | 229 | 4 | 1.71 |
| in Anisole | | | | | |
| 1% Polysulfone | Anisole | 233 | 0 | 233 | 100 |
| in Anisole | | | | | |
| 1% PES in GBL | ArF Thinner | 107 | 110 | −3 | −2.80 |
| 1% PES in GBL | GBL | 107 | 0 | 107 | 100 |

The wet etch rates of masking films formed from Example 1 (after a 250° C./60 s bake) were investigated in various wet etchants. The film thickness of the masking films were measured using a Nanospec 9200 and plotted as a function of soaking time of the coated wafers. The etch rates were calculated as the slope of the linear regressions. The results in Table 2 show that the polysulfone film can be removed rapidly with a baking temperature at 250° C. using Fab friendly solvents. Anisole, GBL, GBL/nBA 70:30 and NMP show faster wet etch rates than cyclohexanone for the Polysulfone film.

TABLE 2

| | Wet Etch Rate |
|---|---|
| Solvent | (Å)/sec |
| Cyclohexanone | 81.50 |
| Anisole | 156.83 |
| GBL | 148.97 |
| GBL/nBA 70:30 | 154.47 |
| NMP | 151.37 |

The wet etch rates of masking films formed from Example 1 (after a 350° C./60 s bake) were investigated in various wet etchants. The film thicknesses and etch rates were determined as described above. The results in Table 3 show that the Polysulfone film can be removed rapidly with a baking temperature as high as 350° C. by Fab friendly solvents.

TABLE 3

| | Wet Etch Rate |
|---|---|
| Solvent | (Å)/sec |
| Cyclohexanone | 71.32 |
| Anisole | 80.85 |
| GBL | 77.53 |
| GBL/nBA 70:30 | 85.48 |
| NMP | 81.38 |

The wet etch rates of masking films formed from Example 1 (after a 250° C./60 s bake) were investigated as a function of the average molecular weight of the polysulfone. The film thicknesses and etch rates were determined as described above. The data in Table 4 demonstrate that the wet etch rates can be controlled by varying the molecular weight of the Polysulfone. Specifically, lower molecular weight Polysulfones show faster wet etch rates in cyclohexanone while retaining low etch rates in ArF thinner solvent, which is beneficial for the throughput of the Polysulfone film removal process.

TABLE 4

| | Cyclohexanone Wet Etch | ArF Thinner Wet Etch |
|---|---|---|
| MW of Polysulfone | Rate (Å/sec) | Rate (Å/sec) |
| 9848 | 616.3 | 80.0 |
| 18901 | 570.1 | 69.0 |
| 25481 | 538.5 | 51.2 |
| 28630 | 490.2 | 4.3 |
| 32386 | 476.5 | 3.3 |
| 36143 | 400.1 | 2.1 |
| 39899 | 219.5 | 1.2 |
| 47412 | 67.4 | 0.1 |

In order to demonstrate that a masking film can reduce the metal contamination, total metal contaminations on back side and bevel (Ti atoms/cm²) was analyzed by inductively coupled plasma mass spectrometry (ICP-MS). A first wafer was used without a masking layer. The edge of a second wafer was coated by a masking film which is 8.5% Polysulfone with an average molecular weight of 47412 in Anisole and baked at 250° C./60 sec. Both wafers were then: (1) coated with a Ti containing metal hardmask formulation which is 9.1% Ti containing polymer synthesized as in synthesis example 7 of U.S. Pat. No. 9,315,636 (Yao et al.; the content of which is hereby incorporated herein in its entirety) in PGMEA/PGME=70/30, (2) rinsing the metal hardmask film on the edge of the wafer with an edge bead remover (PGMEA/PGME=30/70), (3) baking the metal hardmask film at 250° C./60 sec and (4) cleaning off the masking film on the edge of wafer with Anisole . The data in table 5 show that the metal contamination in the hardmask film is reduced in the wafer treated with the masking film as compared to the wafer that was not treated with the masking film.

TABLE 5

| | Total Metal Contamination on | |
|---|---|---|
| Spin-on Metal | Back Side and Bevel (Ti atoms/cm²) | |
| Oxide Hardmask | EBR (PGMEA/PGME) only | With masking film |
| Formulation | without masking film | @ 250° C./60 sec |
| Spin-on TiOx | 8.5E+11 | 3.3E+9 |
| Hardmask | | |

### Process Examples 3

Process example 3 was prepared by dissolving 567.26 g of polysulfone (obtained from Aldrich, CAS 25135-51-7) and 402.74 g of the low Mw polysulfone from synthesis example 1 in 8730 g of anisole.

The masking composition from process example 3 was spin coated on a silicon wafer and baked at 250° C. Then it was soaked in either ArF Thinner or cyclohexanone. The film thickness was measured before and after soak. The results are shown in Table 6.

TABLE 6

| | | FT | FT | | Wet |
|---|---|---|---|---|---|
| | | Before | After | Film | Etch |
| | | Soak | Soak | Loss | Rate |
| Formulation | Soak Solvent | (Å) | (Å) | (Å) | Å/sec |
| Process example 3 | ArF Thinner | 5416 | 5210 | 206 | 3.43 |
| Process example 3 | Cyclohexanone | 5469 | 645 | 4824 | 482.40 |

The data in Table 6 demonstrate the wet etch rate contrast in ArF Thinner and cyclohexanone.

### Process Example 4

Process example 4 was prepared by dissolving 21.170 g of the polymer from synthesis example 2 and 28.830 g of polymer from synthesis example 3 in 450.00 g of anisole.

The masking composition from process example 4 was spin coated on a silicon wafer and baked at 250° C. Then it was soaked in either ArF Thinner or cyclohexanone. The film thickness was measured before and after soak. The results are shown in Table 7.

TABLE 7

| | | FT | FT | | Wet |
|---|---|---|---|---|---|
| | | Before | After | Film | Etch |
| | | Soak | Soak | Loss | Rate |
| Example | Soak Solvent | (Å) | (Å) | (Å) | Å/sec |
| Process example 4 | ArF Thinner | 6013 | 5963 | 53 | 0.83 |
| Process example 4 | Cyclohexanone | 6116 | 511 | 5605 | 560.50 |

The data in Table 7 demonstrate the wet etch rate contrast in ArF Thinner and cyclohexanone.

### Process Example 5

Process Example 3 was repeated with polysulfone (obtained from Aldrich, CAS 25135-51-7) only, and the masking composition was spin coated on a silicon wafer and baked at 250° C. Then it was soaked in either ArF Thinner or cyclohexanone. The film thickness (FT) was measured before and after soak. The results are shown in Table 8.

TABLE 8

| | | FT | FT | | Wet |
|---|---|---|---|---|---|
| | | Before | After | | Etch |
| | | Soak | Soak | | Rate |
| Example | Soak Solvent | (Å) | (Å) | Film Loss (Å) | Å/sec |
| Process | ArF Thinner | 4923 | 5963 | −40 | −0.667 |
| Example 5 | | | | | |
| Process | Cyclohexanone | 4998 | 618 | 4280 | 87.38 |
| Example 5 | | | | | |

1. A masking composition for forming a masking film comprising:
a. a polymer comprising a unit having structure (I): 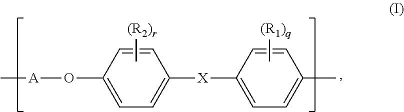
wherein
X is selected from the group consisting of —SO₂—, —C(═O)— and —O—;
A is a direct bond or A is selected from the group consisting of structure (II): 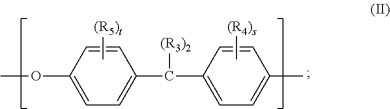
R₁, R₂, R₃, R₄ and R₅ are each independently selected from the group consisting of H, halo, (C₁₋₃) alkyl, (C₁₋₃) fluorinated alkyl, hydroxy, (C₁₋₃) alkoxy, and (C₁₋₃) alkyl carbonyl; and
q, r, s and t are each independently selected from the group consisting of 0, 1, 2, 3 and 4; and
b. an organic solvent, wherein the polymer has an Mw of between 10000 and 50000 average molecular weight of less than 50000.

2-4. (canceled)

5. The composition of claim 1, wherein the polymer comprises a mixture of polymers each comprising a unit having structure (I).

6. The composition of claim 5, wherein the mixture of polymers comprises a first polymer having an Mw greater than 40000 and a second polymer having an Mw less than 40000.

7. The composition of claim 5, wherein the mixture of polymers comprises a first polymer having an Mw greater than 30000 and a second polymer having an Mw less than 30000.

8. The composition of claim 5, wherein the mixture of polymers comprises a first polymer having an Mw greater than 40000 20000 and a second polymer having an Mw less than 20000.

9-10. (canceled)

11. The composition of claim 1, wherein X is —SO₂—.

12. The composition of claim 1, wherein each R₁, each R₂, each R₄ and each R₅ is independently selected from the group consisting of H, F, and (C₁₋₃) alkyl.

13. (canceled)

14. The composition of claim 1, wherein each R₃ is independently selected from the group consisting of H, F, (C₁₋₃) alkyl, and (C₁₋₃) fluorinated alkyl.

15-16. (canceled)

17. The composition of claim 1, wherein the polymer has structure (III):

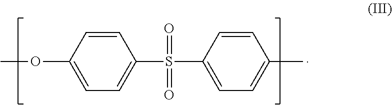

18. The composition of claim 1, wherein the polymer has structure (IV):

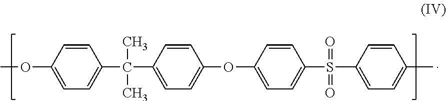

19. The composition of claim 1, wherein the polymer has structure (V):

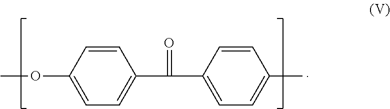

20. The composition of claim 1, wherein the polymer has structure (VI):

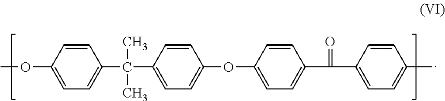

21. The composition of claim 1, wherein the organic solvent is selected from the group consisting of anisole, cyclohexanone, gamma butyro lactone (GBL), N-methyl-2-pyrrolidone, di-(C₁₋₆) alkyl ketones, (C₁₋₆) alkyl acetates and mixtures thereof.

22. The composition claim 1, wherein the polymer is present in the composition in an amount between 0.1 wt % and 20 wt %.

23. The composition of claim 1, wherein the polymer is present in the composition in an amount between 3 wt % and 15 wt %.

24. A method of manufacturing an electronic device comprising the steps of:
a. applying the masking composition of claim 1 onto an edge of a substrate; and
b. heating the masking composition at a temperature between 150° C. and 350° C. and for a time between 60 s and 120 s to form a masking film.

25. The method of claim 24, wherein the masking composition is applied onto the substrate by a spin-on coating process.

26. The method of claim 24, further comprising the steps of:
c. applying a hardmask composition onto the substrate and the masking film;
d. rinsing the hardmask composition with an edge bead remover to remove at least a portion of the hardmask composition that is in contact with the masking film;
e. heating the hardmask composition to form a hardmask; and
f. removing the masking film.

27-36. (canceled)

37. A masking composition for forming a masking film comprising:
a. a polymer comprising a unit having structure (I): 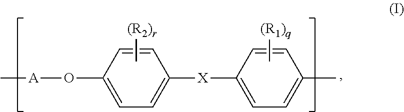
wherein
X is selected from the group consisting of —SO₂—, —C(═O)— and —O—;
A is a direct bond or A is selected from the group consisting of structure (II): 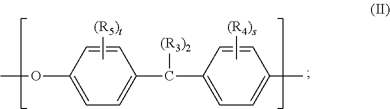
R₁, R₂, R₃, R₄ and R₅ are each independently selected from the group consisting of halo, (C₁₋₃) alkyl, (C₁₋₃) fluorinated alkyl, hydroxy, (C₁₋₃) alkoxy, and (C₁₋₃) alkyl carbonyl; and
q, r, s and t are each independently selected from the group consisting of 0, 1, 2, 3 and 4; and
b. an organic solvent comprising anisole,
wherein the polymer has an Mw of not greater than 50000.

38. A masking composition for forming a masking film comprising:
a. a first polymer comprising a unit having structure (IV): 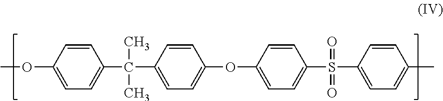
having an Mw of greater than 40000 and not more than 50000;
b. a second polymer comprising a unit having structure (IV): 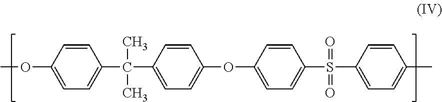
having an Mw of less than 15000; and
c. an organic solvent comprising anisole.
